(19) United States
(12) Patent Application Publication
(10) Pub. No.: US 2026/0333622 A1
(43) Pub. Date: Oct. 22, 2026

(54) Liquid Cooling Assemblies For Data Storage Drives

(71) Applicant: NetApp, Inc., San Jose, CA (US)

(72) Inventors: Edward Joseph Fiore, Ramsey, MN (US); Gregory Jay Samson, Albertville, MN (US)

(73) Assignee: NetApp, Inc., San Jose, CA (US)

(21) Appl. No.: 19/185,533

(22) Filed: Apr. 22, 2025

(51) Int. Cl. H05K 7/20; G06F 1/20

(52) U.S. Cl. CPC H05K 7/20254; G06F 1/20

(57) ABSTRACT

Provided herein are various enhancements for providing cooling and thermal regulation for data storage drives that are mounted into high-density chassis configurations. In one example, an apparatus includes a cooling plate comprising integrated fluid channels and coupling features that mount onto a case of a data storage drive. A flange of the cooling plate comprises external fluid connections configured to couple the fluid channels to a cooling fluid supply.

### TECHNICAL BACKGROUND

Data storage drives have become increasingly deployed in data centers in high-density configurations. These high-density configurations include rack-mounted chassis into which the data storage drives can be mounted, with the chassis then mounted into racks. In data centers, solid state drives (SSDs) are increasingly deployed due to corresponding performance, reliability, and speed compared to traditional rotating magnetic hard disk drives (HDDs). However, as SSDs continue to evolve, their performance improvements come with increased power consumption and consequently higher heat generation. High-performance SSDs, especially those used in data centers, can generate significant amounts of heat during operation.

For example, the new Enterprise and Datacenter Storage Form Factor (EDSFF) E3 form factor of drives is rapidly replacing the existing 2.5-inch and U.2 drive form factors in the data storage market. The power levels for these drives currently range from 25 Watts (W) for the E3.S size up to 70 W for the E3.L.2T size. This increase in power density can create thermal issues for the drives, the corresponding chassis/racks, and downstream components within the storage devices. If heat is not effectively managed, it can lead to thermal throttling, where drives reduce performance to prevent overheating, impacting the efficiency and reliability of a data center.

Traditional cooling methods, such as air cooling, are often employed for high-density computing deployments (e.g., data centers). Air cooling, while widely used due to its simplicity and cost-effectiveness, has inherent inefficiencies, such as low thermal conductivity, limiting air cooling effectiveness for transferring heat away from components. In densely packed environments, air cooling systems can struggle to maintain adequate airflow, leading to hot spots and uneven cooling. These systems often require powerful fans to move large volumes of air, which consume significant energy and contribute to higher operational costs. The noise generated by high-speed fans can also be disruptive in certain environments. Furthermore, air cooling solutions can be bulky, taking up valuable space within enclosures and limiting the ability to add or upgrade components. Maintenance is another challenge, as air cooling systems can accumulate dust and debris, reducing efficiency and necessitating regular upkeep.

### SUMMARY

Provided herein are various enhancements for providing cooling and thermal regulation to data storage drives that are mounted into high-density chassis configurations. In the examples herein, cooling plates are coupled to data storage drives, with the cooling plates having internal fluid channels for circulating cooling fluid to and from external fluid connections. The use of cooling plates can potentially alleviate inevitable thermal issues as the adoption increases for new high-powered and high-density solid state drive (SSD) form factors (e.g., E3 types).

In one example implementation, an apparatus includes a cooling plate comprising integrated fluid channels and coupling features that mount onto a case of a data storage drive. A flange of the cooling plate comprises external fluid connections configured to couple the fluid channels to a cooling fluid supply.

In another example implementation, a system comprises a chassis configured to accept data storage drive assemblies each having a data storage drive coupled to a cooling plate. The system includes a fluid distribution manifold comprising sets of fluid connections configured to removably couple to corresponding drive fluid connections of the cooling plates.

In yet another example implementation, a method includes removing a panel from a case of a data storage drive, and applying a cooling plate to the data storage drive to replace the panel such that protrusions of the cooling plate thermally couple to one or more electrical components of the data storage drive. The cooling plate comprises a flange that at least partially overhangs from the cooling plate over an edge of the data storage drive and includes external fluid connections configured to removably couple to a cooling fluid supply.

In a further example, a system includes a rackmount enclosure having storage drive slots that removably accept storage drive assemblies. Each of the storage drive assemblies comprise a solid-state storage drive (SSD) removably coupled to a corresponding electrical connector of a slot, and a cooling plate thermally coupled to a component of the SSD and having drive fluid connections removably coupled to corresponding slot fluid connections. A fluid distribution manifold is configured to provide the slot fluid connections and couple the slot fluid connections to an external fluid source.

This Overview is provided to introduce a selection of concepts in a simplified form that are further described below in the Detailed Description. It may be understood that this Overview is not intended to identify key features or essential features of the claimed subject matter, nor is it intended to be used to limit the scope of the claimed subject matter.

### BRIEF DESCRIPTION OF THE DRAWINGS

Many aspects of the disclosure can be better understood with reference to the following drawings. While several implementations are described in connection with these drawings, the disclosure is not limited to the implementations disclosed herein. On the contrary, the intent is to cover all alternatives, modifications, and equivalents.

FIG. 1 illustrates a storage drive assembly having an example cooling plate in an implementation.

FIG. 2 illustrates fluid connections for a storage drive assembly having an example cooling plate in an implementation.

FIG. 3 illustrates back side fluid manifold connections for data storage drive chassis examples in an implementation.

FIG. 4 illustrates front side fluid manifold connections for data storage drive chassis examples in an implementation.

FIG. 5 illustrates a rackmount environment with example fluid manifold connections for data storage drives in an implementation.

FIG. 6 illustrates a method of manufacturing and assembly of storage drive assembly having a cooling plate in an implementation.

### DETAILED DESCRIPTION

As performance and power density of computing components increase in data center environments, the thermal limitations of air cooling have become more pronounced, which can lead to storage drive overheating and potential hardware failures. Liquid cooling offers higher thermal conductivity, more efficient heat transfer, targeted cooling, quieter operation, and lower energy consumption., among other advantages. Liquid cooling can be a highly effective thermal management solution used in various high-performance and heat-intensive applications. In high-performance computing (HPC), liquid cooling systems utilize water blocks, pumps, radiators, and reservoirs to dissipate heat more efficiently than traditional air cooling, enabling higher component densities, performance, and overclocking capabilities.

The examples herein provide liquid cooling techniques and assemblies for storage drive thermal management. By ensuring effective heat dissipation, the examples herein can prevent thermal throttling, enhance the reliability of storage drives, and maintain high performance desired for data center environments. The example implementations herein can achieve compatibility with various drive and chassis designs and form factors, ensuring serviceability, and minimizing the risk of leaks, all of which are useful for the practical deployment of such liquid cooling solutions in data centers.

The Figures below focus on specific storage drive types and form factors, namely the Enterprise and Datacenter Storage Form Factor (EDSFF) E3.S and E3.L form factors for solid state storage drives (SSDs). However, other form factors and storage drive types can be employed, including 3.5" HDDs. These include other form factors promulgated by the EDSFF standards, such as E1.S and E1.L, as well as existing form factors for SSDs that include M.2 and 2.5" U.2 SSDs. The various EDSFF storage drives can use SFF-TA-1002 x4 or x8 connectors, among others.

Each storage drive typically comprises a circuit board that houses solid state memory circuitry (e.g., flash memory chips), as well as communication interfacing and power distribution electronics. Typically, an external connector is provided for a storage drive, over which read, write, and maintenance transactions can be initiated and handled, as well as data transferred. A case or enclosure is included to contain all of the internal components of the drive, with only the drive connector having an external mounting for coupling of the drive to a connector, cable, backplane, or other interface. While the example implementations are discussed in the context of solid state drives (SSDs), it should be understood that the examples can instead be applied to other types of storage drives, including magnetic media, optical media, and other types of data storage media.

Various implementations of the present technology provide for a wide range of technical effects, advantages, and/or improvements to computing systems and components. For example, various implementations may include one or more of the following technical effects, advantages, and/or improvements: 1) non-routine and unconventional designs for the integration of SSD liquid cooling in data centers; 2) non-routine and unconventional integration of cold plate technology into SSD drives by replacement of a top cover, wrapping a cold plate around a drive longitudinal end to reduce overall assembly width, and implementation of an external manifold solution for improved serviceability and risk management; 3) unique dual-connection system with keyed, integrated connectors for straightforward and safe connection/disconnection; 4) an assembly design that includes assembly width reduction; 5) unique balancing of cooling efficiency with form factor constraints; 6) unique design to minimize the risk of cooling fluid leaks; 7) unique external manifold design for improved serviceability and leak prevention; and/or 8) non-routine and unconventional prototyping and testing methodology for cold plate integration.

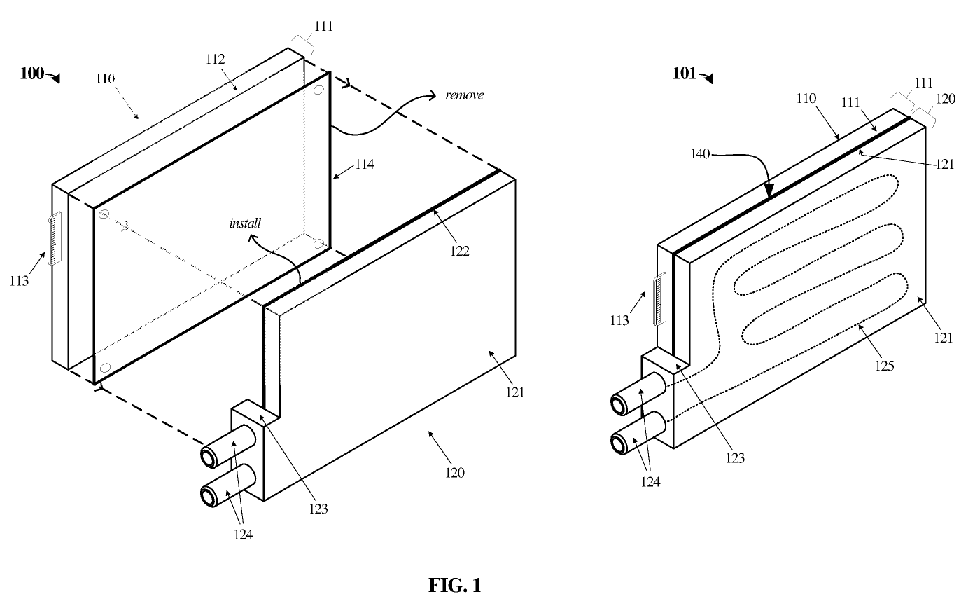

Turning now to a first example implementation, FIG. 1 is presented. FIG. 1 includes view 100 showing an exploded view of storage drive assembly 110 during an assembly process. View 101 shows an assembled storage drive assembly 110 with some internal features highlighted. Storage drive assembly 110 includes data storage drive 111 and cooling assembly 120.

In operation, cooling assembly 120 is mated to data storage drive 111. Cooling assembly 120 is configured to transport thermal energy from data storage drive 111 to cooling fluid circulated in integrated fluid channels of cooling assembly 120. External fluid connections 124 of cooling assembly 120 carry cooling fluid to and from cooling assembly 120, which can then remove heat from data storage drive 111. Thus, based on being coupled to a cooling fluid supply which circulates cooling fluid, cooling assembly 120 can provide thermal cooling to data storage drive 111, enabling more performant operation of data storage drive 111, especially for higher power storage drive types and high-density storage chassis arrangements.

In some examples, cooling assembly 120 attaches to an external case or enclosure of data storage drive 111, such as via adhesives, clamps, fasteners, screws, or other techniques. Cooling assembly 120 can have a mating surface or mounting surface configured to contact an exterior enclosure surface or exterior panel of a case of data storage drive 111. The mounting surface of cooling assembly 120 can be mechanically and thermally coupled to an exterior of data storage drive 111. This thermal coupling can include thermally conductive pastes, pads, or other materials, and can include various surface features that provide flush contact with a desired portion of the case of data storage drive 111. Examples of mounting include replacement of enclosure screws or other fasteners of data storage drive 111 with longer fasteners/screws to hold cooling assembly 120 onto data storage drive 111. Clips, adhesives, or mechanical compression from mutual mounting of cooling assembly 120 and data storage drive 111 in a caddy or drive carrier can be employed. For examples that employ adhesives, cooling assembly 120 might be adhered to case 112 of data storage drive 111 with various removable adhesives, thermally conductive pressure sensitive adhesives, or other adhesive types. In such examples, the adhesives can include various types of thermally conductive adhesives which can maintain a mechanical bond across a target operational temperature range. The adhesives might be resins or epoxy types of adhesives with thermally conductive particles embedded therein, or comprising thermally conducive resin material, among other configurations. The adhesives can be selected to support removal of data storage drive 111 from cooling assembly 120 during repair or replacement of components.

In other examples, cooling assembly 120 can replace a portion of the case of data storage drive 111, such as a side panel (e.g., top or bottom panel). Coupling features of cooling assembly 120 (e.g., screws, fasteners, clips, adhesives) can be configured to mount a cooling plate of cooling assembly 120 to data storage drive 111 to replace at least the removed portion of the case. For example, a side plate, shown as panel 114 in FIG. 1, can be removed from data storage drive 111. Cooling assembly 120 can then replace panel 114, and screw into existing cover screw locations that previously held panel 114. Different screw lengths, head types, thread depths, or other properties screws might be employed when replacement of factory-original screws is selected.

Protrusions can be included on a cooling plate of cooling assembly 114 to thermally contact desired components of data storage drive 111, such as for direct contact with heat-generating electronics. The protrusion height, length, sizing, surface area, and other parameters can be dependent based on the specific model/type of storage drive selected as data storage drive 111. However, for any storage drive selected, the protrusions can correspond to the arrangements of circuitry and other heat-generating components mounted to a circuit board of data storage drive 111. In general, the protrusions can comprise thermally conductive elements which extend into an interior space of data storage drive 111 from cooling assembly 120 to thermally contact selected components of data storage drive 111. Various thermally conductive adhesives, pads, pastes, or other materials can be included between the protrusions and the affected components of data storage drive 111. In one example, a selected storage drive might have an arrangement of protrusions on a case panel or cover, and these arrangements of protrusions can be replicated for cooling assembly 114.

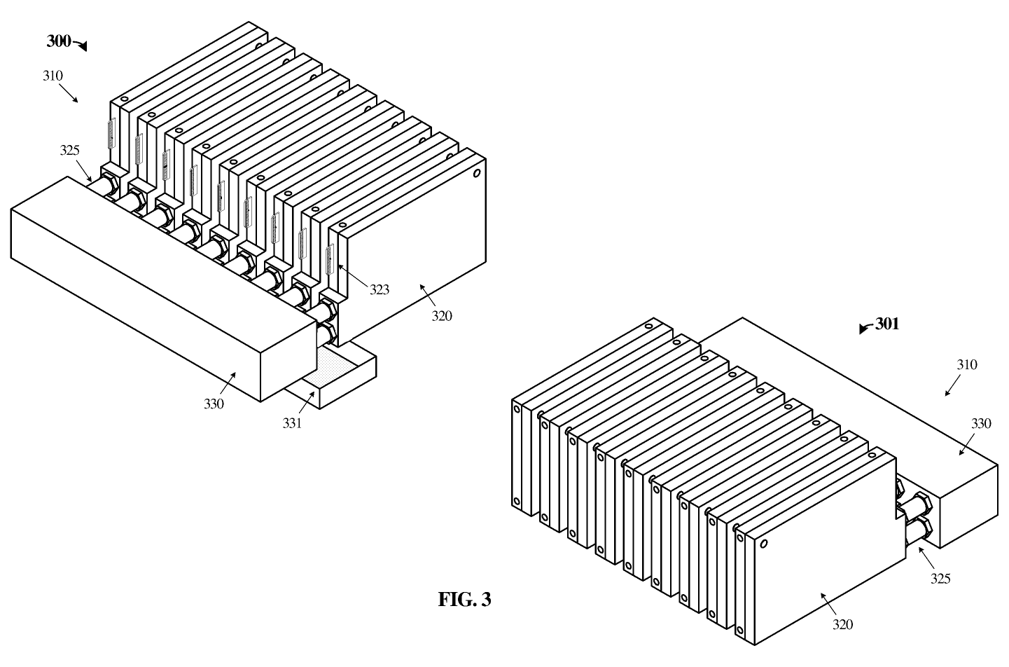

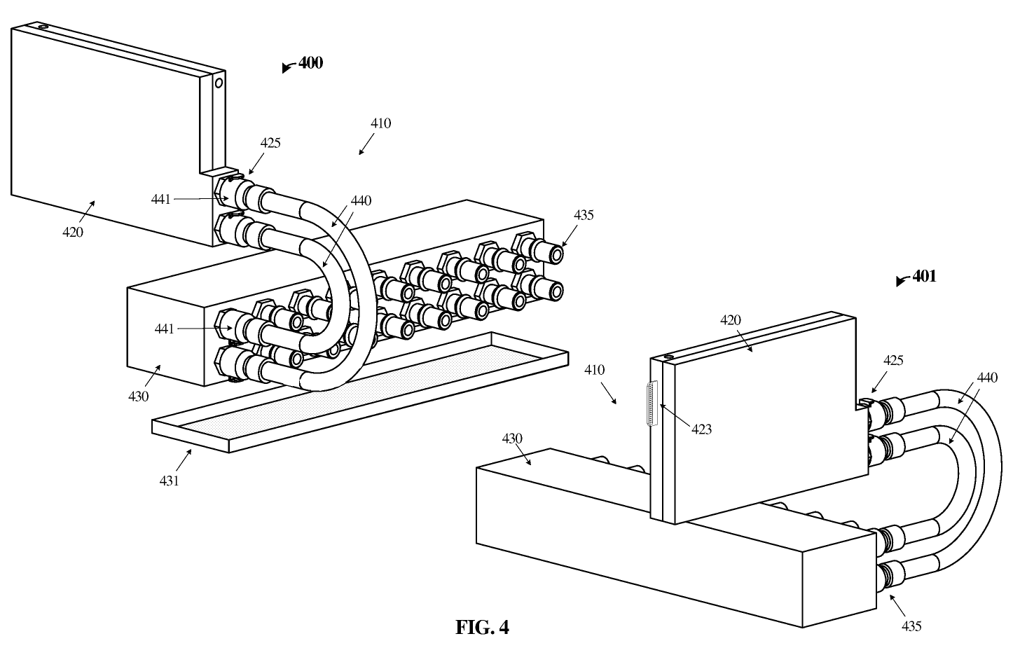

Furthermore, integrating storage drive liquid cooling into existing liquid cooling systems in data centers can be achieved, although single-drive, discrete, or independent cooling systems can be employed for a selected quantity of data storage drives. Many data centers have infrastructure for liquid cooling of chassis of servers or central processing units (CPUs), including pumps, reservoirs, and heat exchangers. For example, rackmount structures can have piping and associated fluid pumps, distribution systems, heat exchangers, and the like for distributing cooling fluid to and from liquid-cooled rack-mounted components. These include pipes which are routed vertically in rackmount systems, with generally horizontal branches configurable to reach selected rackmount chassis and components. The storage drive liquid cooling examples presented herein can be designed to connect to these liquid cooling systems using standardized fluid fittings and connectors. As will be discussed in FIGS. 3 and 4, manifolds (internal or external to a rackmount chassis) can be employed to further integrate multiple instances of storage drive assembly 110 into a rack-mounted arrangement, and provide a centralized point for coolant fluid distribution and collection, reducing the complexity of individual drive connections. The manifolds can couple individual drives to and from a coolant liquid source, such as for a data center or other rackmount environment. This approach can provide additional efficiencies for a storage drive cooling system that leverages data center liquid cooling infrastructure, enhancing overall thermal management efficiency, and reducing the need for additional cooling equipment.

Thus, the examples herein provide for various features and advantages. These include replacing storage drive manufacturer case covers with cooling plates for direct contact with internal drive components and electronics, wrapping cooling assemblies around storage drive ends to increase a diameter of fluid connections while reducing an overall width of the combined drive-cooling plate assembly. Various user-friendly features can be included to make insertion and removal of cooled storage drive assemblies more straightforward, including keyed fittings or self-aligning mating features for fluid connections, as well as leak-proof, no-drip, or dripless fluid connector types. As noted, fluid manifolds can be employed to service a plurality of cooled storage drive assemblies within a chassis, and to enable use of a single shared fluid connection for a rack-mount chassis that supports many liquid-cooled storage drive assemblies. This can increase serviceability and reduce leak instances for corresponding chassis and drives, as well as include common/shared liquid connection points for chassis assemblies.

Turning now to a discussion of the elements of FIG. 1, data storage drive 111 comprises case 112 and drive connector 113, along with various internal components hidden from view and located within case 112. Data storage drive 111 also includes panel 114 which forms a portion of case 112, such as a face or side panel. Drive connector 113 can comprise an EDSFF connector (SFF-TA-1002 x4 or x8), U.2 connector (SFF-8639), U.3 connector, M.2 connector (NGFF), M.3 connector, MCIO connector, Next Generation Small Form Factor (NGSFF/NF1) connector, among others. Storage media internal to case 112 can comprise solid state storage media, such as flash memory, static RAM, NAND flash memory, NOR flash memory, memristors, or other solid state media. Instead of or in addition to solid state media, storage media can comprise magnetic storage, such as hard disk drives or magnetoresistive memory devices, and the like, or can comprise optical storage elements, such as phase change memory.

A storage controller of data storage drive 111 can receive storage transactions, such as read transactions and write transactions over drive connector 113. Responsive to a read transaction, the storage controller can retrieve data from the storage media, and transfer the data for delivery to an associated node that originated the storage transaction. Responsive to a write transaction, the storage controller can write data that accompanies the write transaction to storage media. Thus, drive connector 113 can carry various communications using various storage interfacing standards, such as Peripheral Component Interconnect Express (PCIe) links, Non-Volatile Memory Express (NVMe) links, Ethernet links, or other links, including various links that transport other storage interface communications. These read and write transactions can increase the thermal profile of data storage drive 111, especially in high-volume data center environments servicing many concurrent clients, although any storage drive can benefit from additional cooling as described herein.

Cooling assembly 120 includes housing 121, cooling plate 122, flange 123, external fluid connections 124, and internal fluid channels 125. Housing 121 can comprise various materials that can encase other components of cooling assembly 120 and provide structural rigidity to cooling plate 122 and flange 123. For example, housing 121 can comprise aluminum or alloys thereof, copper materials, polymers, die cast materials, machined metals or polymers, composite materials, or other various materials, including combinations thereof. Selection of materials and housing characteristics can include selections based on thermal conductivity, fluid channel formation and types, weight, cost, material thickness for a selected fluid channel type or heat removal property, mounting/chassis configuration, and other factors. Various fluid seals, gaskets, or adhesives can be optionally included in portions of housing 121 to encase fluid channels and prevent leaks of cooling fluid into an external environment.

The entire stackup thickness (or width) of cooling assembly 120 can have a thickness which can vary based on application and selected drive type. Thicknesses of EDSFF storage drives can vary, but E3 drive thicknesses typically include 7.5 mm (millimeters) and 16.8 mm, and E1 drive thicknesses include 9.5 mm, 15 mm, and 25 mm. For an E3.S or E3.L drive type, a cooling assembly thickness of approximately 5 to 7 millimeters (mm) can be selected to provide for fluid channels, fluid connections, and to fit within an envelope of a chassis slot, although variations are possible. Other dimensions (e.g., length and height) of cooling assembly 120 can also be sized to match or mechanically register with the data storage drive selected. In examples that employ E3.S data storage drives, cooling assembly 120 can generally match corresponding height/length dimensions, including a height of 76 mm and length of 112.75 mm. A thickness (or width) of E3.S drives (7.5 mm) can be greater than a thickness of cooling assembly 120, such that the entire assembly of a storage drive and cooling assembly has a thickness suitable for a selected application or mounting scheme. For instance, the assembly might mount into a chassis slot or have a carrier/caddy that mounts into a chassis slot, and the slot width can define the dimensional envelope of the entire assembly. Thus, while the thickness of the storage drive can vary based on selected model, type, standard, etc., the corresponding thickness of the cooling plate can be selected to keep the entire drive/cooling assembly thickness to within a desired width envelope (i.e., slot width).

Cooling assembly 120 can include coupling features that mount onto a case of a corresponding data storage drive, such as shown for data storage drive 111. In one example, the coupling features can be included on cooling plate 122 or housing 121, and mount cooling plate 122 in place of a removed portion of case 112 of data storage drive 111. FIG. 1 shows panel 114 removed from data storage drive 111, such as by removal of corresponding screws, adhesives, seals, gaskets, or other fastening elements. Panel 114 can be discarded and replaced by cooling assembly 120. In other examples, data storage drive 111 can be manufactured in a configuration to include cooling plate 122 or other features of cooling assembly 120, forming a data storage drive with integrated cooling features. In yet other examples, at least a portion of cooling plate 122 can be integrated with case 112 of data storage device 111, such as protrusions formed into panel 114 that can thermally couple into elements of cooling assembly 120.

Cooling plate 122, also referred to as a cold plate, can be formed from a thermally conductive material, such as metal, carbon composite, ceramic, or other material. When cooling plate 122 comprises a polymer or composite material, thermally conductive portions, such as metal elements, can be included that couple to fluid channels 125. In some examples, such as when cooling plate 122 replaces a panel or portion of case 112 of data storage drive 111, protrusions can be formed into cooling plate 122 that are configured to thermally contact components of data storage drive 121, such as heat-generating components including processing elements, controllers, solid state memory chips, circuit board elements, and other various components. In further examples, housing 121 and cooling plate 122 can form an integrated or monolithic design, formed from the same material which includes integrated fluid channels 125. In such examples, various machining, 3D printing, casting or other techniques can be employed to form the integrated housing and cooling plate.

Fluid channels 125 can comprise etched, molded, or machined channels formed into cooling plate 122, or may instead comprise hoses, tubes, or separate plates with integrated channeling. The selected fluid channel configuration can be selected based on available thickness for a cooling plate, amount of cooling/flow desired for a particular application, fluid viscosities, minimum/maximum fluid flow rates, effectiveness of heat transfer, and other considerations, including cost, material mechanical and thermal conductivity properties, selected manufacturing technique, and design choice. Fluid channels 125 might be accompanied by various thermal coupling elements, to thermally connect fluid channels 125 to cooling plate 122 or other elements. These thermal coupling elements can include fins, thermally conductive bridges, thermal paste or fluid, potting, perforations in cooling plate 122, or other elements. Fluid channels 125 couple to external fluid connections 124 for input/output of circulating cooling fluid, and thus can include additional connection elements or couplers that connect portions of fluid channels 125 to external fluid connections 124. Additionally, external fluid connections 124 and fluid channels 125 comprise materials or coatings which can tolerate any suitable cooling fluid employed, such as water, glycol, preservatives, and other similar fluids or liquids.

External fluid connections 124 are disposed onto or incorporated within flange 123, which is included on a longitudinal end of cooling assembly 120. Flange 123 can be formed as an integral part of housing 121 or cooling plate 122, or may instead be a separate workpiece that is attached by fasteners, couplers, clamps, adhesives, or other fastening elements. Flange 123 is shown as protruding along an edge of case 112 of data storage drive 111, also referred to as wrapping around a portion of case 112, such that an overhang thickness of flange 123 corresponds to no more than a thickness of data storage drive 111. The exact thickness can vary based on the model/type of drive selected, but thicknesses of EDSFF storage drives typically include 7.5 mm (millimeters) and 16.8 mm for E3 types, and thicknesses include 9.5 mm, 15 mm, and 25 mm for E1 types. This configuration of flange 123 can provide for wider diameter fluid connections than would normally be available for just the thickness of housing 121. Flange 123 thus can house drive fluid connections (124) having a diameter greater than a thickness of an edge of the cooling plate, such as the approximately 1/2-inch diameter connections shown.

External fluid connections 124 comprise removably couplable fluid connections with respect to supply lines of a cooling fluid supply (not shown). This configuration enables hot plugging (e.g., dynamic insertion and/or removal) of storage drive assembly 110 into a chassis or other enclosure/mount. In one example, fluid connections 124 can couple or decouple concurrently with electrical connections of connector 112, allowing storage drive assembly 110 to be easily inserted or removed from a chassis. This provides a dual-connection system for both electrical and fluid connections. Various alignment features, such as keyed alignment features or connectors, can be employed to further provide for quick and safe connection/disconnection. Fluid connections 124 can comprise blind-mate dripless couplings, and a chassis can include drip trays or absorbers below connection points to ensure any fluid does not impact other electronics or components.

During mounting of a storage drive with a cooling assembly, gas or air from cooling assembly 120 might be introduced into other fluid channels or supply lines through fluid connections 124. In some examples, gas bleed valves can be included on cooling assembly 120 or a corresponding fluid manifold to support removal of any gas/air after insertion of a cooling assembly into a liquid cooling system. Other examples include pre-filling fluid portions of cooling assembly 120 with liquid before insertion into a chassis or associated cooling system liquid lines. The fluid connections of cooling assembly 120 can comprise “drip proof” varieties with an internal door/seal to contain liquid in a pre-filled cooling assembly before insertion into a chassis or liquid cooling lines.

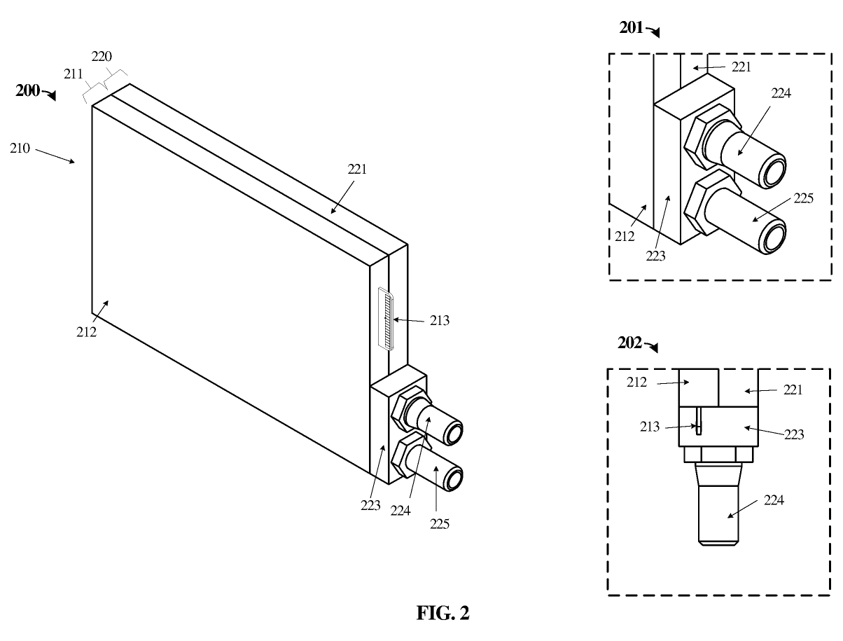

FIG. 2 includes further views of a liquid cooled data storage drive assembly. Specifically, storage drive assembly 210 is shown as having cooling assembly 220 attached to data storage drive 211. Similar elements are shown in FIG. 2 as discussed above in FIG. 1, although variations are possible.

In this example, fluid connections 224-225 on flange 223 are included on a same longitudinal end or edge as electrical connector 213. This configuration can relate to a "blind mate" or back-side coupling of storage drive assembly 210 into an associated chassis, where an operator can insert storage drive assembly 210 into a slot where both fluid and electrical connections are made concurrently on a back side or hidden side of the storage drive assembly internal to a chassis slot. Data storage drive 211 can couple to a backplane or midplane, depending on the chassis configuration.

In addition, blind-mate dripless fluid couplings with keyed connections are shown in FIG. 2. As can be seen in inset views 201 and 202, different stem keying or taper features are included along a length of each of fluid connections 224-225 to differentiate mechanical connections from each other and block incorrect insertion of supply lines to fluid connections 224-225. For example, fluid connection 224 might be designated as an input connection, and thus only an input supply line should be coupled thereto. Likewise, fluid connection 225 might be designated as an output fluid connection, and thus only an output supply line should be coupled thereto. Various check valves or other configurations might be employed to prevent accidental mis-coupling as well.

As can be seen in FIG. 2, cooling assembly 220 is coupled to data storage drive 211, which can be using any of the techniques discussed herein. The size of cooling assembly 220 and the corresponding cooling plate (hidden from view) can vary depending on the power draw or heat dissipation of data storage drive 211, as well as the selected drive type/model. Other factors can include the flow rate of a given rackmount system into which the drive(s) are installed, expected operational temperatures for the external environment and internal components for a storage drive, expected peak workloads, and other factors. For instance, larger or higher flow rate internal cooling channels or tubes might be employed for high heat dissipation devices versus low heat dissipation devices. Alternatively, more thermally conductive materials or fluid channel configurations (i.e., many fins/channels) can be employed for a greater heat exchange property. Variations can include different thicknesses of housings 221 or cooling plate components, including internal features and external connections. Adding cooling assembly 220 to an E3 drive can reduce multi-drive chassis densities by 30-50%, so thus keeping cooling assembly 220 thickness profiles as low as feasible is desirable. Flange 223 can aid in reducing an overall thickness of storage drive assembly 210 with cooling assembly 220 attached and larger diameter fluid connections. Without the use of wrap-around flange 223, the overall thickness of storage drive assembly 210 would have to accommodate the diameter of fluid connections 224-225 within the thickness of cooling assembly 220.

FIG. 3 illustrates back side fluid manifold connections for data storage drive chassis examples in an implementation. This configuration can be employed in a chassis or rackmount assembly which can be inserted into a large rackmount environment having associated cooling fluid supply systems with associated pumps, heat exchangers, refrigerator elements, reservoirs, regulators, and fluid connections. View 300 shows a back-side view of drive array 310, and view 301 shows a front-side view of drive array 310. The back and front designations, in this example, discuss a relation to a rackmount chassis (not shown), for which a front side is generally accessible by an operator for insertion and removal of devices from the chassis/rack.

Included in drive array 310 are an example quantity of data storage drives with cooling housings attached thereto, namely nine (9) storage drive assemblies 320. A different quantity of drives and manifold connections can be included in other examples. Each storage drive assembly 320 includes a pair or set of fluid connections 325 as well as electrical connectors. This configuration shows electrical connections on a same 'side' or longitudinal end as fluid connections, referred to as a blind mate configuration with back-side connections. However, other examples, such that those shown in FIG. 4, include fluid connections on a different longitudinal end as the electrical connections (front-side fluid connections).

Thus, drive array 310 comprises at least a portion of a chassis configured to accept data storage drive assemblies each having a data storage drive coupled to a cooling plate. Drive array 310 also includes manifold 330 comprising a fluid distribution manifold having sets of fluid connections configured to removably couple to corresponding drive fluid connections of the cooling plates. In operation, a data storage drive (having a mounted cooling plate/housing) can plug into an external chassis backplane though a drive connector of the data storage drive and concurrently through external fluid connections disposed on a same side of the cooling plate as the electrical connector.

Manifold 330 comprises structural elements configured to mate with storage drive assemblies 320, provide fluid coupling to supply systems, and mount into a corresponding chassis. Manifold 330 can be separate from, or integrated with, a backplane or midplane carrying drive electrical connections. Although not shown in FIG. 3, manifold 330 can include common/shared input/output lines/connections for coupling into further liquid cooling system components. Manifold 330 can comprise various fluid connections shown for mating to storage drive assemblies 320, as well as internal drive input/output and routing features to route cooling fluid to and from a cooling supply system. The internal drive connections within manifold 330 can include various distribution topologies, such as daisy-chained (series) or parallel connections with respect to shared/common manifold external input/output connection.

Manifold 330 can include small reservoir volumes for buffering fluid distribution, baffles for reducing fluid slosh or turbulence. Manifold 330 can optionally include controllable valves for turning on/off various ones of the fluid connections, if desired, for additional hot-plug functionality, dynamic connection/disconnection, maintenance, fluid system cleaning, debug, or other purposes. The flow rate provided by manifold 320 to individual drive assemblies can vary based on different factors, including heating/cooling requirements of the selected drive type/models, composite minimum fluid flows needed for all connected drives, fluid line diameter, pump pressure capability, heat removal needs, target temperatures for individual drives, and other factors. Manifold 330 can be formed from materials that contact the fluid which are compatible with the particular cooling liquid or fluid employed, including water or glycol and any preservatives, anti-freeze additives, and other various compounds.

Manifold 330 thus shows a back-side or chassis-internal manifold configuration. This configuration can be employed within a storage drive chassis or enclosure, and can support concurrent back-side liquid and electrical connections for individual drives into an electrical mid/backplane and manifold. Manifold 330 might be accompanied by drip tray 331 (shown in view 300) underneath the drive fluid connections to catch any drips from drive connection/disconnection. Evaporative features can be included in a corresponding chassis, such as fans, airflow channels, wicking materials, or heating elements to evaporate dripped fluid and prevent contamination or ingress with other components.

FIG. 4 illustrates front side fluid manifold connections for data storage drive chassis examples in an implementation. This configuration can be employed in a chassis or rackmount assembly which can be inserted into a large rackmount environment having associated cooling fluid supply systems with associated pumps, heat exchangers, refrigerator elements, reservoirs, regulators, and fluid connections. View 400 shows a front-side view of drive array 410, and view 401 shows a back-side view of drive array 410. The back and front designations, in this example, discuss a relation to a rackmount chassis (not shown), for which a front side is generally accessible by an operator for insertion and removal of devices from the chassis/rack.

Included in drive array 410 are a plurality of fluid connections for data storage drives with cooling housings attached thereto, namely nine (9) sets of fluid connections 435 on manifold 430. One example storage drive assembly 420 is shown, and it should be understood that additional instances of this storage drive assembly can be included. Storage drive assembly 420 includes a pair or set of fluid connections 425 as well as electrical connector 423. This configuration shows electrical connections on a different or opposite 'side' or longitudinal end as fluid connections, referred to as front-side cooling connections.

Thus, drive array 410 comprises at least a portion of a chassis configured to accept data storage drive assemblies each having a data storage drive coupled to a cooling plate. Drive array 410 also includes manifold 430 comprising a fluid distribution manifold having sets of fluid connections configured to removably couple to corresponding drive fluid connections of the cooling plates. In operation, a data storage drive (having a mounted cooling plate/housing) can plug into an external chassis backplane though a drive electrical connector of the data storage drive. External fluid connections are disposed on a different side of the cooling plate as the electrical connector and are configured to couple to cooling fluid supply lines to a supply manifold of the cooling fluid supply through corresponding tubing.

Manifold 430 comprises structural elements configured to mate with storage drive assemblies 420, provide fluid coupling to supply systems, and mount into a corresponding chassis. Manifold 430 can be separate from, or integrated with, a backplane or midplane carrying drive electrical connections. Manifold 430 can comprise various fluid connections 435 shown for mating to fluid connections 425 of storage drive assemblies, as well as internal features to route cooling fluid to and from a cooling supply system. Manifold 430 might include small reservoir volumes for buffering fluid distribution, baffles for reducing fluid slosh or turbulence, and optionally valves for turning on/off various ones of the fluid connections, if desired. The flow rate provided by manifold 420 to individual drive assemblies can vary based on different factors, including fluid line diameter, pump pressure capability, heat removal needs, target temperatures for individual drives, and other factors. Manifold 430 can be formed from materials that contact the fluid which are compatible with the particular cooling liquid or fluid employed, including water or glycol and any preservatives, anti-freeze additives, and other various compounds.

In addition, fluid lines 440 are shown in FIG. 4 to make fluid connections between manifold 430 and individual storage drive assemblies (420). An input and an output fluid line are included in each set of fluid lines 440, with ends of the fluid lines having connectors or couplers 441. These include press-fit couplers which can form a leak-proof seal when connected, as well as leak-proof, no-drip, or dripless fluid connector types.

The amount of drip volume permitted during connection/disconnection can vary, as well as if blind-mate (back side) fluid connections or front-side fluid connections are employed. Examples include quick-disconnect couplers or ends for hoses which can include check valves or doors/flaps to prevent backflow and prevent leaks or drips when decoupled. Also, keyed or self-aligning mating features for fluid connections can be included, and the key or alignment features can be provided to prevent coupling of an input line to an output line, and vice versa, or to enforce a desired fluid flow direction for the connections. Fluid couplers/connectors can be selected to support the flow rates, temperatures, pressures, and leak/drip requirements for individual cooling plates and manifold-based systems, as well as have dimensional envelopes suitable for the deployed chassis slot width/thicknesses, among other considerations.

Although the fluid connections and drip descriptions are in the context of FIG. 4, these can also apply to the other fluid connection examples discussed herein. Manifold 430 thus shows a front-side or external manifold configuration. This configuration can be employed next to a storage drive chassis or enclosure, such as in a 1U rackmount slot, among other sizes. Manifold 430 might be accompanied by drip tray 431 (shown in view 400) underneath the drive fluid connections to catch any drips from drive connection/disconnection for evaporation, collection, draining, or other handling.

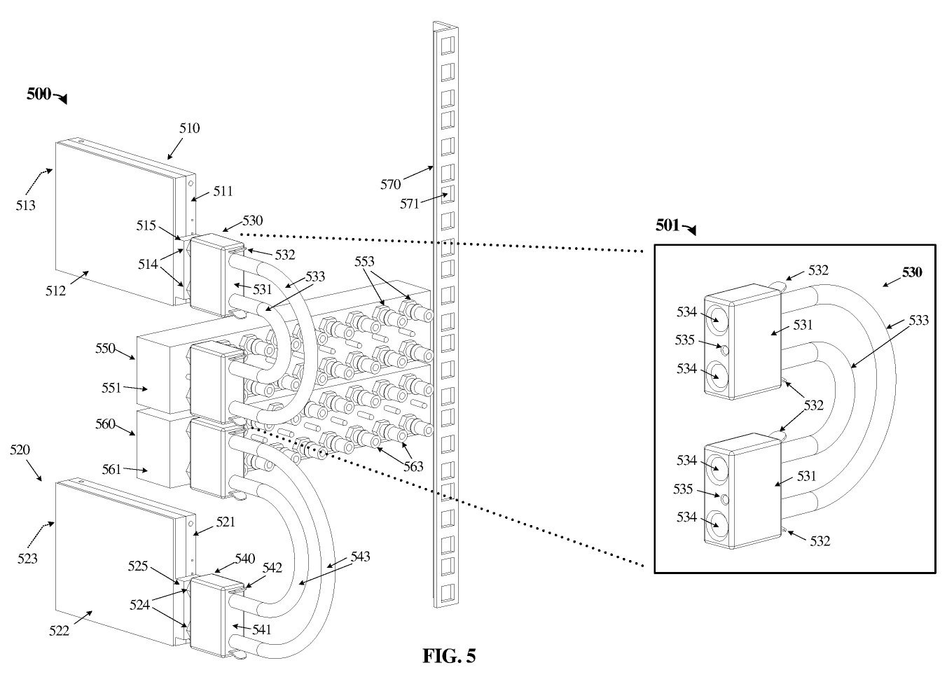

FIG. 5 illustrates a rackmount environment with example fluid manifold connections for data storage drives in an implementation. View 500 illustrates a rackmount configuration implemented in a rackmount shelf system that includes mounting rails, posts, cabinets, and other components to which rack-mountable chassis or enclosure can be installed. A rackmount shelf system can also include power supplies, cooling fans/features, indicator lights, and other various features (not shown). Specifically, a portion of a 19-inch rackmount system is shown in view 500, namely rackmount post 570 having mounting holes 571. Various chassis or enclosures can be mounted via holes 571 to post 570, and other posts/rails can be included but are omitted to highlight the certain features. View 500 might correspond to a front side or back side of a rackmount system.

The rackmount configuration of view 500 includes two sets of storage drive assemblies, with exemplary storage drive assemblies 510 and 520 included for each set. One set of storage drive assemblies includes storage drive assembly 510, and is positioned above fluid manifold 550. A second set of storage drive assemblies includes storage drive 520, and is positioned below fluid manifold 560. Various chassis, enclosures, storage drive slots, mounting hardware, and other various components can be included, but are omitted from FIG. 5 for clarity. For example, a larger quantity of storage drives seen in FIG. 3 might be included.

Storage drive assemblies 510 and 520 each comprise various types of data storage drives (511 and 521), such as SSDs or other storage drives. Storage drive 511 comprises internal storage media and control/interfacing components, as well as an electrical drive connector 513 (hidden from view) on one longitudinal end of the drive. Cooling plate 512 is coupled to a panel or surface of an enclosure of storage drive 511, and includes cooling fluid connections 514 on flange 515. In this example, fluid connections 514 and connector 513 are on an opposite longitudinal ends of storage assembly 510. However, fluid connections 514 and connector 513 might instead be positioned on a same side of storage assembly 510. Storage drive assembly 520 can include similar features as storage drive assembly 510, namely storage drive 521, cooling plate 522, drive connector 523, drive fluid connections 524, and flange 525.

Fluid manifolds 550 and 560 are positioned between the collections of storage drives, and each can comprise a 1U rackmount assembly, although variations are possible depending on the quantity of connections, positioning of fluid connections, and other factors. Fluid manifold 550 includes manifold body 551 which houses various internal routes, channels, piping, or internal fluid connections, as well as drive fluid connections 533. Drive fluid connections 533 can be configured to couple to storage drives in pairs/sets such than an input and output connection for fluid transfer is provided. Additionally, fluid manifold 550 can couple to a cooling fluid source/sink, which can occur over any of connections 533, or other connections (not shown) on a front, side, or back of manifold body 551. Manifold 560 includes similar features as manifold 550, namely manifold body 561 and manifold drive fluid connections 563.

To couple among fluid connections of a fluid manifold and individual storage drive assemblies, fluid connector assemblies are provided. These include example fluid connector assemblies 530 and 540 which couple fluid manifolds 550 and 560 to storage drive assemblies 510 and 520, respectively.

Detailed view 501 shows example features for fluid connector assembly 530, and similar features can apply to fluid connector assembly 540, albeit with different lengths of connections. Fluid connector assembly 530 forms a dual cooling tube assembly. Fluid connector assembly 530 includes connector body 531, connector locks 532, connector tubes 533, fluid connections 534, and keyed features 535. Fluid connector assembly 540 includes similar features as fluid connector assembly 530. Namely, fluid connector assembly 540 includes connector body 541, connector locks 542, connector tubes 543, fluid connections 544, and keyed features 545.

In view 501, connector body 531 forms fluid connections 534 that couple to fluid hoses 533 and drive/manifold fluid connections (e.g., 514, 524, 553, and 563). Keyed feature 535 which can have a mating post or pin on a cooling plate flange (e.g., 515 or 525) which ensures alignment of fluid connections during hot-plugging, insertion, removal, and other operations. Moreover, keyed feature 535 can prevent connections in a reversed fluid orientation, such that drive fluid input connections couple to manifold output fluid connections, and vice versa. Connection clips or locks 532 are also included which can be press-to-release or other various types of connection locks. Locks 532 ensure that inadvertent removal of fluid connector assembly 530 is prevented. In some examples, locks 532 allow for connection of fluid connector assembly 530 to a corresponding mate and then lock into place after proper/full insertion, preventing removal until exertion of a removal force (i.e., squeezing of finger tabs of locks 532 together, for example).

The amount of drip volume permitted during connection/disconnection can vary, as well as if blind-mate (back side) fluid connections or front-side fluid connections are employed. Examples include quick-disconnect couplers or ends for hoses which can include check valves or doors/flaps to prevent backflow and prevent leaks or drips when decoupled. Fluid couplers/connectors can be selected to support the flow rates, temperatures, pressures, and leak/drip requirements for individual cooling plates and manifold-based systems, as well as have dimensional envelopes suitable for the deployed chassis slot width/thicknesses, among other considerations.

The examples above, such as seen in FIG. 5, can include various implementations of data storage drive assemblies with fluid-cooled SSDs. In one example, a system includes a rackmount enclosure having storage drive slots that removably accept storage drive assemblies. Each of the storage drive assemblies comprise a solid-state storage drive (SSD) removably coupled to a corresponding electrical connector of a slot, and a cooling plate thermally coupled to a component of the SSD and having drive fluid connections removably coupled to corresponding slot fluid connections. A fluid distribution manifold is configured to provide the slot fluid connections and couple the slot fluid connections to an external fluid source. The system can also include the component of the SSD comprising at least one among a case panel of the SSD, an electrical component of the SSD, and a chassis of the SSD. The system can also include the fluid distribution manifold configured to provide the slot fluid connections on a same side of the storage drive assemblies as the electrical connectors of the slots. The system can also include the fluid distribution manifold configured to provide the slot fluid connections on a different side of the storage drive assemblies as the electrical connectors of the slots.

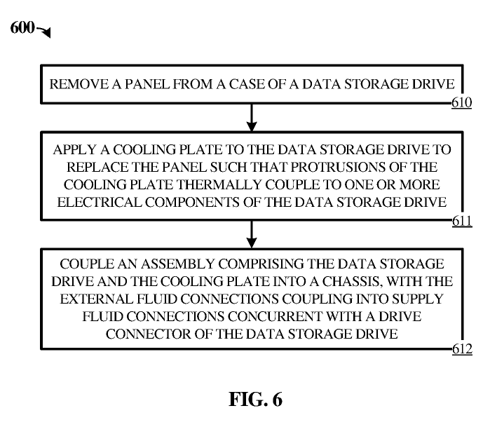

FIG. 6 illustrates a method of manufacturing and assembly of storage drive assembly having a cooling plate in an implementation. Operations 600 show various techniques for coupling a cooling plate or cooling housing to a data storage drive, as well as for coupling the combined assembly into a corresponding chassis or manifold. Although the operations of FIG. 6 discuss one example implementation of replacing a panel of a storage drive with a cooling assembly, it should be understood that other configurations can instead be employed, such as coupling a cooling assembly without removal/replacement of a panel of a storage drive or integration of a storage drive with various cooling features noted herein.

Turning now to operations 600, operation 610 includes removing a panel from a case of a data storage drive, such as panel 114 from data storage drive 111 of FIG. 1. This can include removing screws, adhesives, seals, or other elements that hold a panel of the data storage drive onto a remainder of the data storage drive, such as a frame or drive chassis.

Next, operation 611 includes applying a cooling plate to the data storage drive to replace the panel such that protrusions of the cooling plate thermally couple to one or more electrical components of the data storage drive. In terms of the elements of FIG. 1, cooling plate 122 and cooling housing 121 of cooling assembly 120 can be attached to data storage drive 111 in place of panel 112. Alignment of protrusions of cooling plate 122 with corresponding components of data storage drive 111 can be provided by alignment features that are used to mount and/or couple cooling assembly 120 to data storage drive 111. This can include various pre-existing screw holes that previously held on panel 112, among other configurations. Also, cooling assembly 120 comprises flange 123 that at least partially overhangs from the cooling plate over an edge of the data storage drive 111 and includes external fluid connections 124 configured to removably couple to a cooling fluid supply.

Then, once cooling assembly 120 has been assembled, operation 612 includes coupling an assembly comprising the data storage drive and the cooling plate into a chassis, with the external fluid connections coupling into supply fluid connections concurrent with a drive connector of the data storage drive. For one example implementation, such as shown in FIG. 3, back-side fluid connections can be employed with both electrical and fluid connections being concurrently made in a blind-mate fashion into a back/mid plane and fluid manifold. In another example implementation, such as shown in FIG. 4, front-side fluid connections can be employed, with electrical connections on a back side of a data storage drive assembly and fluid connections on a front side of a data storage drive assembly. The front side fluid connections might employ tubes or hoses to link to a manifold, although other configurations are possible. Once electrical and fluid connections are made, the corresponding data storage drive assembly can operate to service data storage operations as well as remain below a target operating temperature using the internal cooling features of a cooling plate.

The functional block diagrams, operational scenarios and sequences, and flow diagrams provided in the Figures are representative of exemplary systems, environments, and methodologies for performing novel aspects of the disclosure. While, for purposes of simplicity of explanation, methods included herein may be in the form of a functional diagram, operational scenario or sequence, or flow diagram, and may be described as a series of acts, it is to be understood and appreciated that the methods are not limited by the order of acts, as some acts may, in accordance therewith, occur in a different order and/or concurrently with other acts from that shown and described herein. For example, those skilled in the art will understand and appreciate that a method could alternatively be represented as a series of interrelated states or events, such as in a state diagram. Moreover, not all acts illustrated in a methodology may be required for a novel implementation.

The various materials and manufacturing processes discussed herein are employed according to the descriptions above. However, it should be understood that the disclosures and enhancements herein are not limited to these materials and manufacturing processes, and can be applicable across a range of suitable materials and manufacturing processes. Thus, the descriptions and figures included herein depict specific implementations to teach those skilled in the art how to make and use the best options. For the purpose of teaching inventive principles, some conventional aspects have been simplified or omitted. Those skilled in the art will appreciate variations from these implementations that fall within the scope of this disclosure. Those skilled in the art will also appreciate that the features described above can be combined in various ways to form multiple implementations.

What is claimed is:

1. A system, comprising:
a chassis configured to accept data storage drive assemblies each having a data storage drive coupled to a cooling plate; and
a fluid distribution manifold comprising sets of fluid connections configured to removably couple to corresponding drive fluid connections of the cooling plates.

2. The system of claim 1, wherein the sets of fluid connections removably couple to the drive fluid connections on a same side of the data storage drives as drive connectors of the data storage drives.

3. The system of claim 2, wherein the sets of fluid connections removably couple to the drive fluid connections in a blind mate configuration concurrent with the drive electrical connectors.

4. The system of claim 1, wherein the sets of fluid connections couple to the drive fluid connections on a side of the data storage drives opposite from drive electrical connectors of the data storage drives.

5. The system of claim 4, wherein fluid hoses couple the sets of fluid connections of the fluid distribution manifold to the drive fluid connections.

6. The system of claim 1, wherein each of the cooling plates comprise:
integrated fluid channels;
coupling features that mount onto a case of a corresponding data storage drive; and
a flange at a longitudinal end that, based on the cooling plate being mounted to the corresponding data storage drive, protrudes along an edge of the corresponding data storage drive and houses the drive fluid connections having a diameter greater than a thickness of an edge of the cooling plate.

7. The system of claim 6, wherein the coupling features of each of the cooling plates are configured to mount the cooling plate to the corresponding data storage drive to replace at least a removed portion of the case; and
wherein the cooling plate comprises one or more thermally conductive protrusions configured to thermally couple to one or more integrated circuit devices internal to the case of the corresponding data storage device.

8. The system of claim 1, wherein the fluid distribution manifold comprises external fluid connections configured to couple the sets of fluid connections to and from a liquid cooling source.

9. An apparatus, comprising:
a cooling plate including integrated fluid channels and coupling features that mount onto a case of a data storage drive; and
a flange comprising external fluid connections configured to couple the fluid channels to a cooling fluid supply.

10. The apparatus of claim 9, wherein the flange includes a portion at a longitudinal end of the cooling plate that, based on the cooling plate being mounted to the data storage drive, protrudes along an edge of the data storage drive and houses the external fluid connections having a diameter greater than a thickness of an edge of the cooling plate.

11. The apparatus of claim 9, wherein the coupling features are configured to mount the cooling plate to the data storage drive to replace at least a removed portion of the case.

12. The apparatus of claim 11, wherein the cooling plate includes one or more thermally conductive protrusions configured to thermally couple to one or more integrated circuit devices internal to the case of the data storage device.

13. The apparatus of claim 9, wherein the cooling plate comprises a mounting surface configured to be thermally coupled to an exterior panel of the case of the data storage drive.

14. The apparatus of claim 9, wherein the external fluid connections include removably couplable fluid connections with respect to supply lines of the cooling fluid supply.

15. The apparatus of claim 9, wherein the data storage drive, based on the cooling plate being mounted thereto, is configured to plug into an external chassis backplane though a drive connector of the data storage drive and concurrently through the external fluid connections disposed on a same side of the cooling plate as the connector.

16. The apparatus of claim 9, wherein the data storage drive, based on the cooling plate being mounted thereto, is configured to plug into an external chassis backplane though a drive connector of the data storage drive; and
wherein the external fluid connections are disposed on a different side of the cooling plate as the connector and are configured to couple to the supply lines to a supply manifold of the cooling fluid supply through corresponding tubing.

17. The apparatus of claim 9, wherein, based on being coupled to the cooling fluid supply, the cooling plate is configured to transport thermal energy from the data storage drive to fluid circulated in the integrated fluid channels.

18. The apparatus of claim 9, comprising:
a data storage drive coupled to the cooling plate.

19. A method, comprising:
removing a panel from a case of a data storage drive;
applying a cooling plate to the data storage drive to replace the panel such that protrusions of the cooling plate thermally couple to one or more electrical components of the data storage drive; and
wherein the cooling plate comprises a flange that at least partially overhangs from the cooling plate over an edge of the data storage drive and includes external fluid connections configured to removably couple to a cooling fluid supply.

20. The method of claim 19, comprising:
coupling an assembly comprising the data storage drive and the cooling plate into a chassis, with the external fluid connections coupling into supply fluid connections concurrent with a drive connector of the data storage drive.

21. A system, comprising:
a rackmount enclosure having storage drive slots that removably accept storage drive assemblies;
each of the storage drive assemblies comprising a solid-state storage drive (SSD) removably coupled to a corresponding electrical connector of a slot, and a cooling plate thermally coupled to a component of the SSD and having drive fluid connections removably coupled to corresponding slot fluid connections;
a fluid distribution manifold configured to provide the slot fluid connections and couple the slot fluid connections to an external fluid source.

22. The system of claim 21, wherein the component of the SSD comprises at least one among a case panel of the SSD, an electrical component of the SSD, and a chassis of the SSD.

23. The system of claim 21, wherein the fluid distribution manifold is configured to provide the slot fluid connections on a same side of the storage drive assemblies as the electrical connectors of the slots.

24. The system of claim 21, wherein the fluid distribution manifold is configured to provide the slot fluid connections on a different side of the storage drive assemblies as the electrical connectors of the slots.
